(19) United States
(12) Patent Application Publication
(10) Pub. No.: US 2011/0026211 A1
(43) Pub. Date: Feb. 3, 2011

(54) ALL-IN-ONE ELECTRICAL DEVICE AND ASSEMBLY METHOD THEREOF

(75) Inventors: YI-LAN LIAO, Tu-Cheng (TW); TSUNG-HSI LI, Tu-Cheng (TW); SHU-YUN HUANG, Tu-Cheng, Taipei Hsien (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/642,845

(22) Filed: Dec. 20, 2009

(30) Foreign Application Priority Data
Jul. 29, 2009 (CN) 200910304956.X

(51) Int. Cl. G06F 1/16; H05K 7/00; H05K 13/04

(52) U.S. Cl. 361/679.21; 361/729; 29/729; 345/173

(57) ABSTRACT

An all-in-one electrical device includes a front enclosure module, a rear enclosure module, a touch screen, and a middle module. The front enclosure module includes a frame. An opening is defined in the frame. A number of restricting members extend backwards from the frame. The rear enclosure module includes a cover detachably fixed to the frame. The touch screen is received in the frame and exposed through the opening. A forward freedom of motion (FOM) of the touch screen is restricted by the frame. Leftward, rightward, upward and downward FOMs of the touch screen are restricted by the number of restricting members. The middle module is detachably fixed to the frame and received between the frame and the cover. The middle module restricts a backward FOM of the touch screen.

### BACKGROUND

1. Technical Field

The present disclosure relates to all-in-one electrical devices and their assembly methods, and more particularly to a point of sale (POS) terminal and a method for assembling the POS terminal.

2. Description of Related Art

All-in-one electrical devices, such as POS terminals, are widespread used in the service industry. A POS terminal commonly includes a touch screen for facilitating operating the terminal. The touch screen often needs to be serviced or replaced after a long time use to maintain acceptable operability. However, a POS terminal commonly has a complicated assembling structure, which is a disadvantage for servicing or replacing the touch screen. In order to service or replace the touch screen, the POS terminal must be completely disassembled and then reassembled ring upon ring, which wastes much time and labor.

### BRIEF DESCRIPTION OF THE DRAWINGS

FIG. 1 is an isometric view of an embodiment of an all-in-one electrical device.

FIG. 2 is an exploded, isometric view of the all-in-one electrical device in FIG. 1.

FIG. 3 is similar to FIG. 2, but viewed from another perspective.

FIGS. 4 and 5 are partially assembled, isometric views of the all-in-one electrical device in FIG. 3.

FIG. 6 is an assembled, isometric view of the all-in-one electrical device in FIG. 3.

FIG. 7 is a partially assembled, isometric view of another embodiment of an all-in-one electrical device.

### DETAILED DESCRIPTION

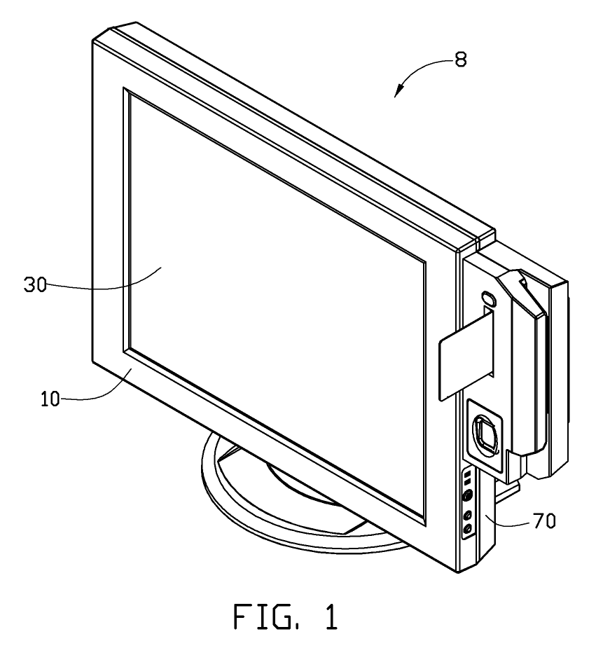

Referring to FIGS. 1 to 3, an embodiment of an all-in-one electrical device 8 includes a front enclosure module 10, a touch screen 30, a middle module 50, and a rear enclosure module 70.

The front enclosure module 10 includes a rectangular frame 11 having four sides. The frame 11 defines an opening 100 in a center of the frame 11. The opening 100 is rectangular bounded by the four sides. Four restricting members 101 extend rearward from the sides bounding the opening 100, respectively. A first mounting pole 103 extends rearward from each corner of the frame 10. Each first mounting pole 103 defines a mounting hole (not labeled) along an extending direction of the first mounting pole 103. Two spaced second mounting poles 105 extend rearwards from the frame 10 between adjacent first mounting poles 103. Each second mounting pole 105 defines a mounting hole (not labeled) along an extending direction of the second mounting pole 105.

The touch screen 30 is rectangular having a substantially larger area than the opening 100.

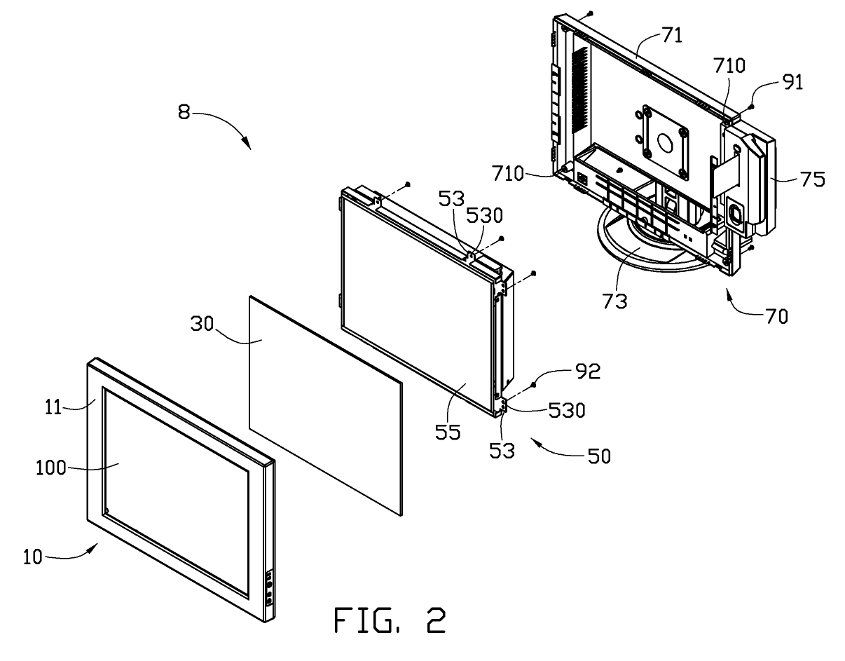

The rear enclosure module 70 includes a cover 71, a support 73, and a card reader 75 for reading a magnetic card. The cover 71 has a rectangular shape corresponding to the frame 11. Four first mounting holes 710 are defined in corners of the cover 71, corresponding to the first mounting poles 103 of the frame 11. The support 73 is fixed to the back side of the cover 71 for supporting the cover 71. The card reader 75 is mounted to a right side (see FIGS. 1 and 2) of the cover 71.

The middle module 50 includes a rectangular bracket 51 having a substantially smaller area than the frame 11. Eight tabs 53 extend from top, bottom, left and right sides of the bracket 51 corresponding to the second mounting poles 105 of the frame 11. A second mounting hole 530 is defined in each tab 53. A plurality of electronic parts is mounted to or in the bracket 51. The plurality of electronic parts may include a motherboard (not shown) and a memory (shown) mounted in the bracket, a display screen 55 mounted to the front side of the bracket 51, a hard disk drive (HDD) 57 mounted to the back side of the bracket 51, and so on. A groove 570 may be defined in the back side of the bracket 51 for accommodating the HDD 57.

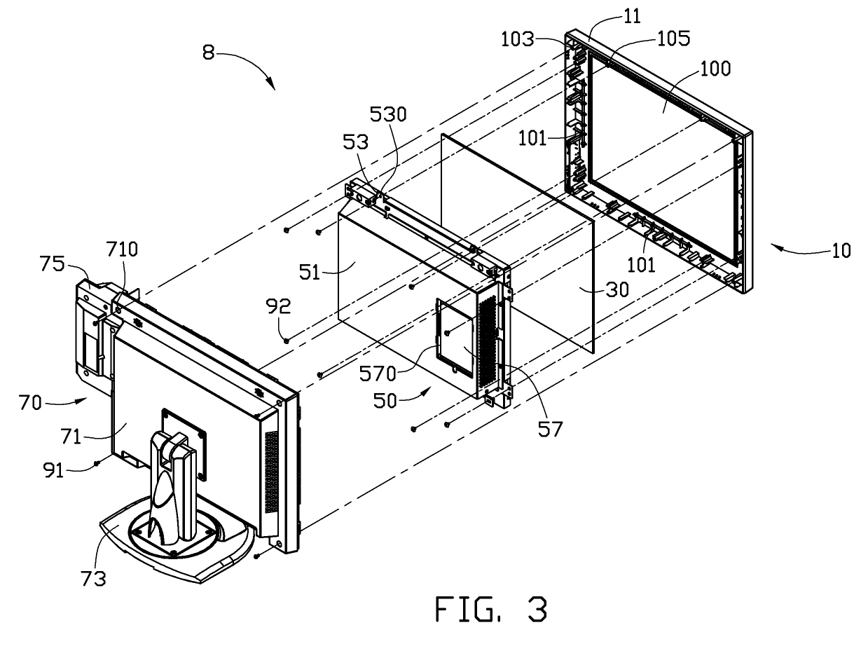

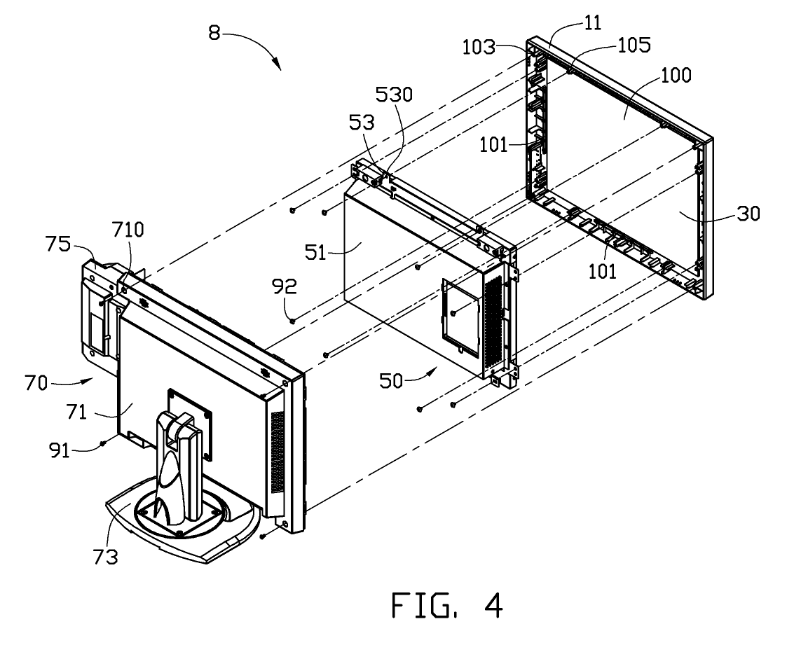

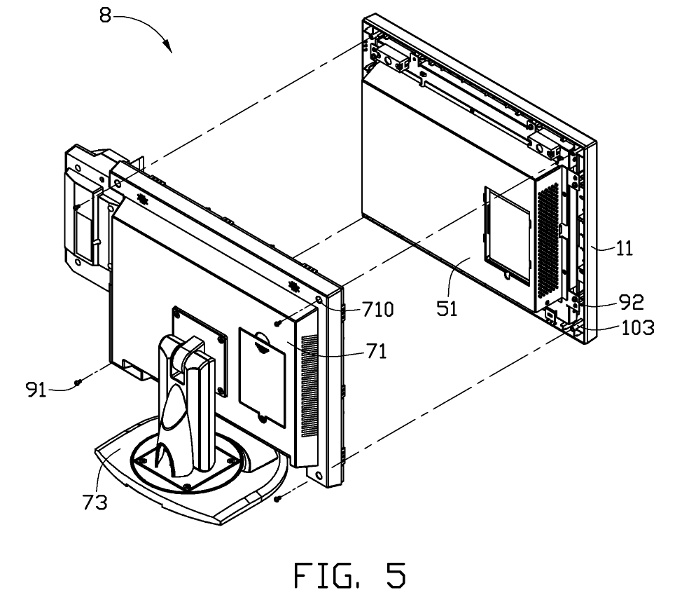

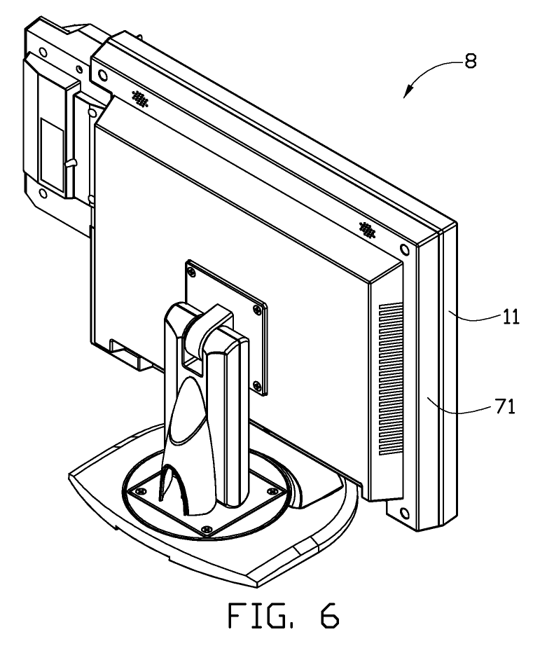

Referring to FIGS. 3 to 6, three assembly steps for the device 8 are shown. In the first step as shown in FIGS. 3 to 4, the touch screen 30 is received in the frame 11 and four sides of the touch screen 30 abut against the restricting members 101 correspondingly. Therefore, a forward freedom of motion (FOM) of the touch screen 30 is restricted by the frame 11, and leftward, rightward, upward and downward FOMs are restricted by the restricting members 101. In the second step as shown in FIGS. 4 to 5, eight screws 92 are inserted through the second mounting holes 530 of the tabs 53 of the bracket 51 and engaged in the mounting holes of the second mounting poles 105 of the frame 11 correspondingly. Therefore, the middle module 50 is mounted to the front enclosure 10, pressing the touch screen 30 to restrict a backward FOM of the touch screen 30. In the third step as shown in FIGS. 5 to 6, four screws 91 are inserted through the first mounting holes 710 and engaged in the mounting holes of the first mounting poles 103 correspondingly. Therefore, the rear enclosure module 70 is mounted to the front enclosure 10, and the middle module 50 is received between the rear enclosure module 70 and the front enclosure module 10.

In other embodiments, if necessary, additional screws 91 and 92 and corresponding mounting features may be employed, in order to assemble the modules 10, 30 and 50 even more securely.

When the touch screen 30 needs to be serviced or replaced, only three disassembly steps are needed, too. The screws 91 are disassembled, so as to detach the rear enclosure module 70 from the front enclosure module 10. The screws 92 are disassembled, so as to detach the middle module 50 from the front enclosure module 10. The touch screen 30 is pushed from an outside of the front enclosure module 10 to detach the touch screen 30 from the front enclosure module 10.

It is noted that the threaded connections via the screws 91 and 92 are selected in the present embodiment is to meet a requirement of keeping liquid out of the device 8. In other embodiments, if the requirement is not needed or not important, the threaded connections may be replaced by other known connections, such as clipping connections and snapping connections.

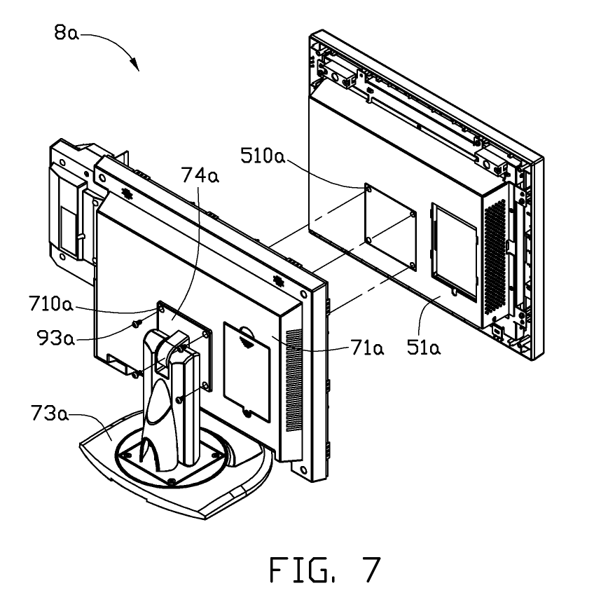

Referring to FIG. 7, a second embodiment of an all-in-one electrical device 8a is shown, differing from the embodiment in FIG. 5 only in that an additional fixing feature is employed. In detail, a support 73a of the device 8a forms a square mounting plate 74a at a top of the support 8a. Four first through holes 710a are defined in the mounting plate 74a. Four second through holes (not shown) are defined in a cover 71a of the device 8a, corresponding to the first through holes 710a. Four screw holes 510a are defined in a bracket 51a of the device 8a, corresponding to the first through holes 710a. Four screws 93a are inserted though the first through holes 710a of the support 8a and second through holes of the cover 71a, and engaged in the screw holes 510a of the bracket 51a correspondingly, so as to fix the support 8a, the cover 71a and the bracket 51a together. Correspondingly, when the device 8a is disassembled for servicing or replacing its touch screen, one more step, disassembling the screws 93a, is needed. Although one more step is added because of the additional fixing feature, the assembly of the device 8a is even more secure.

The module structures of the devices 8 and 8a simplify disassembly and reassembly processes for servicing or replacing a touch screen. In fact, at least two-thirds of workload of disassembly and assembly can be saved, when the device 8 or 8a is employed instead of known products in the market.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An all-in-one electrical device comprising:
a front enclosure module comprising a frame, wherein an opening is defined in the frame, and a plurality of restricting members extends backwards from the frame;
a rear enclosure module comprising a cover detachably fixed to the frame;
a touch screen received in the frame and exposed through the opening, wherein a forward freedom of motion (FOM) of the touch screen is restricted by the frame, and leftward, rightward, upward, and downward FOMs of the touch screen are restricted by the plurality of restricting members; and
a middle module detachably fixed to the frame and received between the frame and the cover, wherein the middle module restricts a backward FOM of the touch screen.

2. The all-in-one electrical device of claim 1, wherein the frame is rectangular, four first mounting poles extend rearward from four corners of the frame respectively, the cover has a rectangular shape corresponding to the shape of the frame, four first mounting holes are defined in the cover corresponding to the first mounting poles, a first screw is extended through each first mounting hole and engaged in the corresponding first mounting pole to detachably fix the cover to the frame.

3. The all-in-one electrical device of claim 2, wherein two spaced second mounting poles extend from the frame between every two adjacent first mounting poles, the middle module comprises a bracket and a plurality of electronic parts mounted to or in the bracket, a second mounting hole is defined in the bracket corresponding to each second mounting pole, a second screw is extended through each second mounting hole and engaged in the corresponding second mounting pole to detachably fix the bracket to the frame.

4. The all-in-one electrical device of claim 3, wherein the plurality of electronic parts comprises a display screen mounted to the front side of the bracket.

5. The all-in-one electrical device of claim 3, wherein the plurality of electronic parts comprises a hard disk drive (HDD) mounted to the back side of the bracket.

6. The all-in-one electrical device of claim 5, wherein a groove is defined in the back side of the bracket, and the HDD is accommodated in the groove.

7. The all-in-one electrical device of claim 1, wherein the rear enclosure module comprises a card reader mounted to the cover.

8. The all-in-one electrical device of claim 1, wherein the rear enclosure module comprises a support fixed to the cover to support the cover.

9. The all-in-one electrical device of claim 8, wherein the support forms a mounting plate at a top of the support, a plurality of first through holes is defined in the mounting plate, a plurality of second through holes are defined in the cover corresponding to the plurality of first through holes, a plurality of screw holes is defined in the middle module corresponding to the plurality of first through holes, a screw is inserted though each first through hole and the corresponding second through hole to be engaged in the corresponding screw hole to fix the support.

10. An assembly method for an all-in-one electrical device, the method comprising:
providing a frame defining an opening and having a plurality of restricting members on the frame, a touch screen, a bracket, and a cover;
mounting a plurality of electronic parts to the bracket to form a middle module by the bracket and the plurality of electronic parts;
receiving the touch screen in the frame and exposing the touch screen through the opening, wherein a forward freedom of motion (FOM) of the touch screen is restricted by the frame, and restrict leftward, rightward, upward and downward FOMs of the touch screen are restricted by the plurality of restricting members;
detachably fixing the bracket to the frame, to restrict a backward FOM of the touch screen by the middle module; and
detachably fixing the cover to the frame, to receive the middle module between the frame and the cover.

11. The method of claim 10, further comprising:
mounting a card reader to an outer surface of the cover.

12. The method of claim 10, further comprising:
mounting a support to the cover to support the cover.
